(19) United States
(12) Patent Application Publication
(10) Pub. No.: US 2010/0141274 A1
(43) Pub. Date: Jun. 10, 2010

(54) Method for Measuring the Thickness of Multi-Layer Films

(75) Inventors: Albert Keller, Rueti (CH); Markus Haenggli, Rueti (CH); Philipp Weber, Rueti (CH); Peter Stuker, Rueti (CH)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hch. Kuendig & Cie. AG, Rueti (CH)

(21) Appl. No.: 12/084,175

(22) PCT Filed: Oct. 2, 2006
(86) PCT No.: PCT/EP2006/009786

§ 371 Date: Apr. 21, 2009

(30) Foreign Application Priority Data
Oct. 28, 2005 (EP) 05405613.0
Dec. 14, 2005 (EP) 05405697.3

(51) Int. Cl. G01B 7/02; G01R 27/26; G01B 11/02

(52) U.S. Cl. 324/671; 356/503

(57) ABSTRACT

The invention relates to a method for determining the thickness of multi-layer films (13) comprising layers consisting of various non-conductive materials. According to said method, the thickness of the multi-layer film (13) is measured by a first sensor (17) and a second sensor (16) and optionally additional sensors, whereby all the sensors take a measurement at the same location under the same conditions if possible. The first sensor (17) and the second (16) or additional sensors generate different measured values for layers of the multi-layer film (13) of the same thickness consisting of the same material (13). The measured signals of the sensors (16, 17) are fed to a computer (18), which determines the total thickness of the multi-layer film (13) and/or the thickness of the individual layers of the multi-layer film (13) from the different measured values of the first sensor (17) and the second (16) or additional sensors.

The invention relates to a method for the determination of the thickness of multi-layer films in accordance with the preamble of the independent patent claim 1. Multi-layer films of plastic are built up of a plurality of layers of different materials. Frequently used so-called thermoplastics are polyethylene (PE), polypropylene (PP), polyamide (PA), ethylene-vinyl-alcohol copolymers (EVOH) and others.

The multi-layer films are manufactured from the various thermoplastics by coextrusion or multi-layer extrusion. Known extrusion methods of this kind are blow extrusion and flat extrusion. In blow extrusion, so-called blow films are produced. The melt is extruded during the blow extrusion out of a ring nozzle and formed into a hose. Air is blown into the hose in order to dilate it. The hose is then laid flat, in many cases is cut into two or more webs and is wound up. During the flat film extrusion the melt is extruded from a slit nozzle.

In the manufacture of multi-layer films various thermoplastics with various properties are simultaneously extruded through multiple nozzles and united to the multi-layer film. In many cases it is necessary to introduce so-called bond promoters (HV) between individual layers of the multi-layer film. The bond promoters have the task of improving the bond between layers of the multi-layer film.

Multi-layer films are used in large quantities for the packaging of food. One speaks in this connection of barrier plastics. These multi-layer films have layers which are of low permeability for, for example, oxygen, moisture or otherwise for certain substances which leads to an improved shelf life of the food. For the packaging of food multi-layer films are also used as shrinkable films, as cooking bags, as sterile packaging for dairy products etc. Typical barrier layer films have, for example, a construction

### PE or PP

### HV

### BARRIER LAYER (PA, EVOH)

### HV

### PE or PP.

Further details concerning multi-layer films, the materials that are used for them and their properties as well as their manufacture can be found in readily comprehensible form in the book “Kunststoff-Folien, Herstellung, Eigenschaften, Anwendung (plastic films, manufacture, properties, uses)” by Joachim Nentwig, Carl Hanser Verlag München Wien, 1994.

In the manufacture of films in general, but in particular also in the manufacture of multi-layer films, the thickness of the films is monitored and, if deviations occur, for example during the manufacture of flat films, the width of the slit of the extrusion nozzles is changed, in order to manufacture as far as possible films of the same thickness. In blow film extrusion, the temperature of the melt or of the cooling air or the quantity of the cooling air is changed locally.

In order, for example, that the quality of the blow film is the same over the entire periphery, the thickness must be uniform over the entire periphery as far as possible. A uniform thickness is amongst other things necessary in order to ensure, for example, uniform printing during the further processing of the film. In order to monitor a uniform thickness in production or to regulate it through setting elements in the blow head the thickness profile of the film must be measured.

By way of example the following sensor types are known for the thickness measurement of films.

Capacitive sensors which are influenced by the dielectric constant and/or the damping factor of the film. Capacitive sensors can measure in reflection or in transmission.

Sensors which operate and measure with ionizing radiation, with back-scattering or with absorption.

Sensors which operate and measure in transmission using infrared absorption.

Sensors which operate and measure optically using interference methods.

Sensors which mechanically or pneumatically measure the thickness after the film has been laid flat.

Sensors which measure thermally.

Sensors which use ultrasound and measure transit times, damping, reflection and/or phase shifts.

The problem which is to be solved with the invention will be explained with reference to the combination of capacitive sensors with sensors which determine the film thickness with reference to back-scattering or ionizing radiation. With a multi-layer film it is not only the intention for the total thickness of a film to be as uniform as possible over the whole film. It is also necessary that the individual layers are of constant thickness as far as possible.

The measurement signals of capacitive sensors are dependent on the dielectric constant of the material to be measured. The measurement signals of capacitive sensors which operate in accordance with the reflection principle are practically directly proportional to the thickness of a film and to the dielectric constant of the material of the film. The dielectric constants of certain materials are temperature-dependent.

Sensors which operate capacitively in accordance with the reflection principle are, for example, used with advantage for the measurement of the film thickness at the film bubble of blow film extrusion plants. In order to detect the thickness profile of a film bubble on line, a sensor is guided on a ring-like construction around the film bubble. One circuit typically takes 1-2 minutes. The sensor is pressed with a uniform pressure against the film bubble. This enables a very good and accurate online detection of the thickness profile of, for example, PE films.

In the measurement at multi-layer films which consists of a plurality of layers of thermoplastics with, in part, greatly differing dielectric constants, the measurement of the thickness and of thickness profiles can be faulty. This is because the sensor cannot recognize that, for example, the thickness of the total film and also the thickness of one or more of the layers of the multi-layer film are simultaneously changing in such a way that the error which originates from the thickness of the film and the measurement error which originates through the thickness of a layer of the multi-layer film partly or fully compensate each other. The capacitive sensor detects either no change of the thickness or a false change of the thickness or a change of the thickness which is too high or too low.

In U.S. Pat. No. 3,635,620 the combination of a mechanical measurement of the total thickness and a capacitive measurement which is dependent on the different dielectric constants of the film layers is used in order to measure and regulate the average thickness of the two material layers. However, since the thickness is only measured at a single point at the periphery, no thickness profile can be produced.

In US 202/0057096 the fact is exploited that the dielectric constant of the barrier materials PA and EVOH is strongly temperature-dependent. In addition to a first capacitive measurement at a high temperature, a second capacitive measurement is used at a much lower temperature in order to measure the thickness of two different material layers. This lower temperature is however generally only achieved after the laying flat and certainly only several meters after the first measurement point. In this way it is difficult or impossible to precisely measure the same points of the film and the measurement results are severely falsified by the thickness fluctuations in the production direction of the film.

The object of the invention is to provide a method which makes it possible to determine as accurately as possible profiles of the thickness of the individual layers of multi-layer films or profiles of the thickness of groups of layers of multi-layer films, such as, for example, of all barrier layers together.

In accordance to the invention, the method has the features of a characterizing part of the independent claim 1. The dependent claims relate to advantageous embodiments of the invention.

The determination of the thickness and of the thickness profiles of multi-layer films in accordance with the new method utilizes for example a different sensitivity for the dielectric constants of capacitive and reflective sensors and, for example, of sensors which measure on the basis of ionizing radiation. The measured values of the capacitive thickness sensors which operate in accordance with the reflection principle are a product of the thickness of the film and of the relative dielectric constant εᵣ. The measured values of the thickness sensors which for example measure on the basis of ionizing radiation are practically only dependent on the thickness and the specific weight of the material. The measured values of sensors which operate with an optical interference method are just as little dependent on the dielectric constant.

Sensors which operate with ionizing back-radiation or with an optical interference method can be arranged in the running direction of the film directly in front of, after or alongside the sensor which operates capacitively and reflectively.

It is of advantage when both sensors measure the same line on the film as precisely as possible, so that fluctuations of the thickness in the production direction simultaneously enter into the measurement for both sensors. If both sensors are arranged above one another or alongside one another at a specific spacing then they measure on two parallel spiral tracks on the film. The horizontal spacing of these spiral tracks should be smaller by at least a factor of 2 then the corresponding spacing of the regulating members in the blow head. With sensors arranged above one another the spacing of the spiral tracks is small when the take-off speed is large, however, it increases proportionally to the vertical spacing of the two systems and with larger reversing speed of the measuring apparatus.

The said condition is achieved for typical applications when the vertical spacing of the two sensors is smaller than ca. 0.5 m. If both sensors are arranged alongside one another, then the corresponding conditions apply.

If the sensors always rotate in the same direction around the bubble, this is in contrast to the reversing operation, then the sensors which are arranged above one another can also be shifted sidewise precisely as much as is necessary in order to compensate for the offset caused by the combination of take-off speed and rotational speed. Moreover the rotational speed can be matched to the take-off speed.

Through the mentioned or similar measures a situation can be achieved in which the two measurement systems measure as precisely as possible at the same location. In this way they also measure under the same thermal conditions.

Dielectric properties of plastics such as thermoplastics which are used for multi-layer films are to be found for example in the book “Die Kunststoffe and ihre Eigenschaften” (“The Plastics and their Properties”), Hans Domininghaus, Verlag Springer, 1998. On page 128 the dielectric numbers ε, for example, and the dielectric loss factor tan δ for plastics which are used for multi-layer films are graphically shown in dependence on the temperature. From this it is evident, that it can in many cases contribute to a further increase of the measurement accuracy of the sensors when the temperature of the film is also measured and is taken into account in the determination of the correction values and the values of the thickness. Since the dielectric constants for the barrier layer materials PA and EVOH which are frequently used are significantly larger at higher temperature it is also of advantage to carry out the method of the invention at a measurement position at which the film is still very hot.

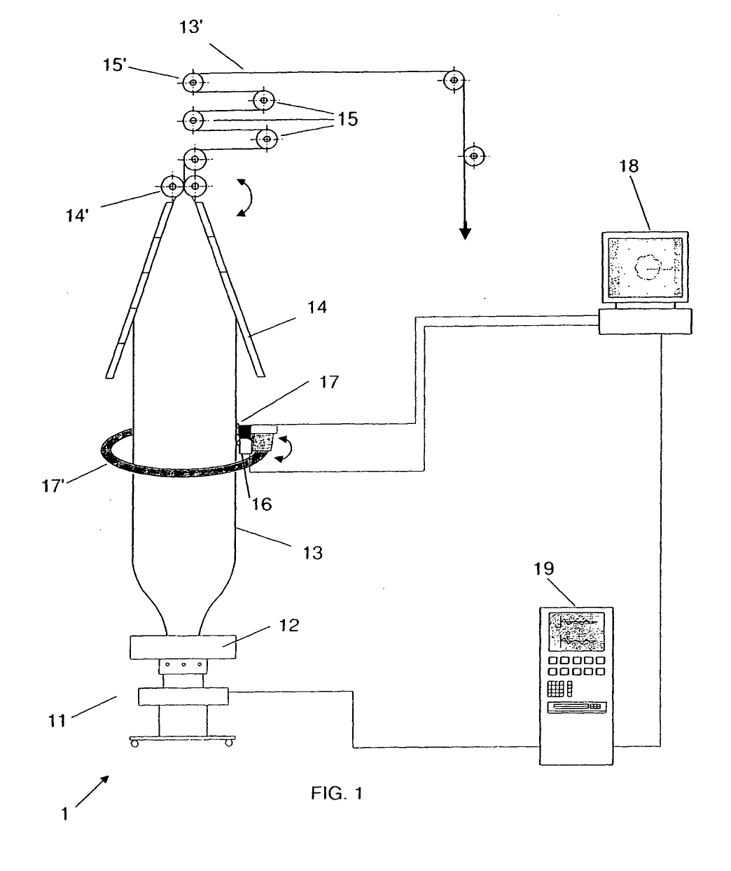

The invention will be explained in the following in more detail with reference to the schematic drawing. The single FIG. 1 shows the schematic principle of a multi-layer film blow extrusion plant at which the thickness is measured and monitored in accordance with the method of the present invention.

The manufacture of films takes place in the blow film extrusion plant 1 as follows: From the extruder with a multiple ring nozzle (not shown) the emerging melt of the various thermoplastics is formed into a hose. This film hose is drawn off at a speed which is larger than the outlet speed of the melt. Through a connection for compressed air in the blow head 11 with a mould tool 12 the hose is inflated to the film bubble 13. At the end of the laying flat section 14 the film bubble is squashed with two squashing rolls 14′. The laid-flat film hose 13′ is then directed (arrow) to a winding device (not shown) and wound up to form a reel.

The thickness of the film is measured at the film bubble 13 with a first sensor 17, for example a capacitive sensor, which operates in accordance with the reflection principle. A second sensor 16, for example a sensor with ionizing radiation, measures as far as possible at the same position or at the same line in the production direction. Both sensors jointly move on a track 17′ in reversing manner to and fro around the film bubble 13. The sensors can also run continuously around the film bubble 13. The reversing procedure or the circuit time lasts approximately half a minute up to several minutes.

After the squashing rolls 14′ the film hose is guided over the turning bars 15 to the fixed roll 15′ and from there to a winder (not shown).

The measured values of the two sensors 16 and 17 are fed to the computer. The computer 18 calculates from them the profile of the total thickness and of the thickness of the individual layers in accordance with the equations in the Tables 2 and 3. The values determined for the thickness of the individual layers or groups of layers and also the total thickness can for example be shown graphically and/or numerically on the screen of the computer 18.

In accordance with the new method one makes use, for multi-layer films, of the assumption, which is entirely permissible in practice, that the multi-layer film consists of two types of thermoplastics. Firstly of the base material, which is mainly a polyethylene (PE) and barrier layer material, such as for example polyamide (PA) or ethylene vinyl alcohol (EVOH) which have a significantly higher dielectric constant εᵣ of 4 to 15. Although multi-layer films are built up of 5 or more different layers this simplifying assumption is admissible since the PE layers among one another and the PA layers among one another have readily comparable and practically the same values for the dielectric constants εᵣ. In this respect and in the following the barrier layers will thus simply be designated with PA. Computationally conclusions can thus also be drawn from the measured values of the two sensors 16, 17 for the thickness of the total multi-layer film relating essentially to the thickness of the PE layers, the thickness of the PA layers and naturally also to the total thickness of the multi-layer film.

The profile of the total thickness and/or the thickness of the part layers which are calculated by the computer 18 are fed to the console 19 with which the plant 1, i.e. the extrusion process, is controlled and regulated and where the data can likewise be shown on a screen. Finally provision can also be made that the console 19 regulates and controls the thickness of the individual layers and of the total multi-layer film as a result of the values for the thickness determined in accordance with the method in the computer 18, as has already been explained earlier.

In the invention one is concerned with the measurement and regulation of the thickness of the total multi-layer film, but also with the measurement of the thickness of layers of different materials, mainly thermoplastics.

In the following it will be shown with reference to an embodiment how the thickness of the PA layers and those of the PE layers can be determined in accordance with the method. In this connection reference is also made to FIG. 1.

TABLE 1
THE DESIGNATIONS USED/THEIR SIGNIFICANCE

| Sign | Significance |
|---|---|
| D1 | Measured thickness value of the sensor 16 which is little dependent |
| | or not dependent on the dielectric constant εᵣ |
| D2 | Measured thickness value of the sensor 17 which is proportional to |
| | the dielectric constant εᵣ |
| DE | Thickness of the PE layer (all layers together which have an εᵣ |
| | similar to PE) |
| DA | Thickness of the PA layer (all layers together which have an εᵣ |
| | similar to that of PA) |
| D | Total thickness of the film D = DE + DA |
| k | Constant, can also be a complicated formula |
| εA | Dielectric constant of PA (i.e. barrier layer) |
| εE | Dielectric constant of PE |

The following preconditions and assumptions are taken to consideration.
All barrier layers (PA, EVOH etc.) having a high εᵣ are considered as a single layer and combined.
All layers with εᵣ similar to PE are combined and considered as a single layer.
The sensor 17 which measures capacitively and reflectively is calibrated to the average value of the total thickness for PE.
The sensor 16 which, for example, measures on the basis of ionizing radiation is calibrated to the average value of the total thickness of the multi-layer film.
The measurement sensitivity of the two measurement systems, i.e. of the two sensors 16 and 17 relating to εᵣ is known.

TABLE 2
BASIC EQUATIONS

| | Equation | | |
|---|---|---|---|
| Device | No. | | Remark |
| Sensor | | D1 = DE + | k = >0 . . . ca. 0.8 for systems |
| 16 | | DA (1 + k) | with a low dependence on εᵣ |
| | | | k = 0, for systems which are |
| | | | independent of εᵣ |
| Sensor | (II) | D2 = DE + | For example εA/εE = 5 |
| 17 | | DA * (εA/εE) | (ca. 1.5 . . . 9) |

TABLE 3
DETERMINATION OF THE PROPORTIONAL THICKNESS OF
PA, OF PE AND OF THE SUM OF TWO THICKNESSES

| | Equation | | |
|---|---|---|---|
| Method | No. | | Remark |
| (II)-(I) | (III) | D2 − D1 = DA | |
| | | (εA/εE − 1 − k) | |
| Simplifi- | (IV) | K = (εA/εE − | Approximation for example |
| cation | | 1 − k) | K = (5 − 1 − 0.6) = 3.4 |
| (IV) in (III) | (V) | DA = (D2 − | Average values or profile |
| | | D1)/K | values |
| From (I) | (VI) | DE = D1 − | |
| | | DA*(1 + k) | |
| | (VII) | D = DE + DA | In accordance with defi- |
| | | | nition of D |

With the formulae in accordance with Table 3 the total thickness of the multi-layer film can be correctly calculated although the measurements of each sensor taken alone have a measurement error which depends on the thickness of the PA layer in relationship to the total thickness of the film.

To a first approximation it is sufficient to insert the values for k and εA/εE mentioned in the table. It is naturally possible to further optimize the method and to determine more precise thickness values. For example with a system having k=0, the correct ratio εA/εE can be determined from the equation III and thus also the applicable εA can be determined for the actual temperature, when the desired value for DA and the average values for a whole profile are inserted for D1 and D2. If the temperature profile of the film is additionally measured at the measurement point 16 and/or 17 then the ratio εA/εE can be determined even more precisely for each individual measurement. This example is, however, solely concerned and above all concerned with showing the principle of the determination of the thickness values from the measured values which are found by the two sensors 16 and 17.

If the assumed values for k and εA/εE do not precisely correspond to reality and/or if the sensor 16 and the sensor 17 are not precisely matched to one another then the calculated K also contains a calibration error component. The proportions of PE and PA which are thus calculated are then not accurate. It can however be shown, for example with a 5% calibration error of the sensor 17, that the profile error resulting from it for the PA profile is less than 0.5% for a proportion of PA of 30%.

In the method for the determination of the thickness of multi-layer films 13 with layers of different non-conductive materials the thickness of the multi-layer film 13 is measured with a first sensor 17 and with a second sensor 16 and optionally with further sensors. The first sensor 17 and the further sensor or further sensors 16 generate different measured values for layers of the same thickness of the same material of the multi-layer film 13. The measurement signals of the sensors 16, 17 are fed to a computer 18 which determines, from the different measured values of the first sensor 17 and of the further sensor or sensors 16, the total thickness of the multi-layer film 13 and/or the thickness of individual layers of the multi-layer film 13.

1. Method for the determination of the thickness of multi-layer films (13) having layers of various non-conducting materials with a first sensor (17), characterized by a further sensor (16) or a plurality of further sensors, wherein all sensors measure the film as far as possible at the same position and under the same conditions, the first sensor and the further sensor or further sensors generate different measured values for layers of the same thickness of the same material of the multi-layer film (13) and the measured signals of the sensors (16, 17) are fed to a computer (18) which determines the total thickness of the multi-layer film (13) and/or of the thickness of individual layers of the multi-layer film (13) from the different measured values of the first sensor (17) and of the further sensor or sensors (16).

2. Method in accordance with claim 1, for the determination of the thickness of multi-layer films (13) of layers of materials with different dielectric constants εᵣ and/or of different dielectric loss factors tan δ.

3. Method in accordance with claim 1, for the determination of the thickness of multi-layer films (13) in which the first sensor (17) measures the dielectric constant εᵣ capacitively in accordance with the reflection method (in reflection) and the second sensor (16) measures the loss factor tan δ of the multi-layer film, capacitively in accordance with the reflection method (by reflection).

4. Method in accordance with claim 1, in which a single sensor measures both the dielectric constant εᵣ and also the dielectric loss factor tan δ and thus serves as the first and the second sensors.

5. Method in accordance with claim 1, in which the first sensor operates with a measurement principle of which the measured values of the thickness are strongly and preferably directly proportionally dependent on the dielectric constant εᵣ of the material of the film, in particular with a sensor which operates and measures using the capacitively and reflectively operating measurement principle and the second sensor operates with a measurement principle the thickness measurement values of which are only weakly dependent on the dielectric constant εᵣ of the material of the film and of the layers of the film, preferably using a sensor which measures the thickness of the film with the back-scattering of ionizing radiation or with a sensor which measures the thickness of the film in accordance with an optical interference method.

6. Method in accordance with claim 1, in which the sensors measure the thickness of the film at the same point of the film or at adjacent points of the film, preferably at the film bubble or at the laid out flat film.

7. Method in accordance with claim 1, in which the computer (18) to which the measured values of two measurement devices are fed which react with different sensitivities to the dielectric constants of the film materials, determines from these measured values the dielectric constants or the ratio of the dielectric constants of the various film materials.

8. Use of the method in accordance with claim 1 in a multi-layer film blow extrusion plant or in a flat film extrusion plant for the measurement, monitoring and/or regulating of the total thickness and/or of the thickness of the individual layers and/or of the thickness of groups of layers, in particular of the barrier layers in multi-layer films (13).
